(19) United States
(12) Patent Application Publication
(10) Pub. No.: US 2026/0305042 A1
(43) Pub. Date: Oct. 1, 2026

(54) DISPLAY PANEL AND DISPLAY DEVICE

(71) Applicant: Tianma Advanced Display Technology Institute (Xiamen) Co.,Ltd., Xiamen (CN)

(72) Inventors: Yangui FENG, Xiamen (CN); Ning ZHANG, Xiamen (CN); Jiaxian LIU, Xiamen (CN)

(21) Appl. No.: 19/221,960

(22) Filed: May 29, 2025

(30) Foreign Application Priority Data
Mar. 28, 2025 (CN) 202510386541.0

(51) Int. Cl. H10H 29/856; H10H 29/85; H10W 90/00

(52) U.S. Cl. CPC H10H 29/856; H10H 29/857; H10W 90/00

(57) ABSTRACT

A display panel includes an array substrate; a plurality of light-emitting units and a plurality of reflective units located on a first side of the array substrate, where the reflective unit includes a first reflective portion, which is located on at least one side surface of the corresponding light-emitting unit; and a transparent portion, which is located on the first side of the array substrate, wherein at least part of the transparent portion is located between the first reflective portion and the light-emitting unit.

### CROSS-REFERENCE TO RELATED APPLICATION

The present application claims priority of Chinese Patent Application No. 202510386541.0, filed on Mar. 28, 2025, the entire content of which is hereby incorporated by reference.

### TECHNICAL FIELD

The present application relates to the field of display technology, in particular to a display panel and a display device.

### BACKGROUND

Micro-LED displays are becoming the mainstream development trend in the display field due to their high brightness, high contrast and excellent reliability. Moreover, with the expansion of market demand for the micro-LED display industry and the continuous expansion of application areas, micro-LED display products are showing diversified development trends. However, since the luminous efficiency of micro-LED drops sharply as its size decreases, it is difficult for micro-LED display products to balance between high resolution and high brightness display.

### SUMMARY

In one aspect, the disclosure provides a display panel, including an array substrate; a plurality of light-emitting units and a plurality of reflective units located on a first side of the array substrate, where the reflective unit includes a first reflective portion, which is located on at least one side surface of the corresponding light-emitting unit; and a transparent portion, which is located on the first side of the array substrate, where at least part of the transparent portion is located between the first reflective portion and the light-emitting unit.

In another aspect, the disclosure provides a display device, including the display panel, and the display panel includes an array substrate; a plurality of light-emitting units and a plurality of reflective units located on a first side of the array substrate, where the reflective unit includes a first reflective portion, which is located on at least one side surface of the corresponding light-emitting unit; and a transparent portion, which is located on the first side of the array substrate, where at least part of the transparent portion is located between the first reflective portion and the light-emitting unit.

It should be understood that the content described in this section is not intended to identify the key or important features of the embodiments of the present disclosure, nor are they intended to limit the scope of the present disclosure. Other aspects of the present disclosure may be understood by those skilled in the art in light of the description, the claims, and the drawings of the present disclosure.

### BRIEF DESCRIPTION OF THE DRAWINGS

In order to more clearly illustrate the technical solutions of the embodiments of the present disclosure, the drawings required for use in the embodiments will be briefly introduced below. Apparently, the drawings described below are merely some embodiments of the present disclosure. For persons having ordinary skills in the art, it should be apparent that the basic concepts of device structure, driving method and manufacturing method disclosed and suggested by the embodiments of the present disclosure may be expanded and extended to other structures and drawings, and should be within the scope of the claims of the present disclosure.

FIG. 1 is a schematic structural diagram of a display panel, in accordance with an embodiment of the disclosure;

FIG. 2 is a top view of a display panel, in accordance with an embodiment of the disclosure;

FIG. 3 is a schematic structural diagram of a light-emitting element in a display panel, in accordance with an embodiment of the disclosure;

FIGS. 4-10 are schematic diagrams of some structures involved in a manufacturing process of a display panel, in accordance with an embodiment of the disclosure;

FIGS. 11-12 are schematic diagrams of some structures involved in another manufacturing process of a display panel, in accordance with an embodiment of the disclosure;

FIG. 13 is a schematic structural diagram of another display panel, in accordance with an embodiment of the disclosure;

FIG. 14 is a schematic structural diagram of another display panel, in accordance with an embodiment of the disclosure;

FIGS. 15-20 are schematic diagrams of some structures involved in another manufacturing process of a display panel, in accordance with an embodiment of the disclosure;

FIG. 21 is a top view of another display panel, in accordance with an embodiment of the disclosure;

FIG. 22 is a schematic structural diagram of another display panel, in accordance with an embodiment of the disclosure;

FIG. 23 is a schematic structural diagram of another display panel, in accordance with an embodiment of the disclosure;

FIG. 24 is a schematic structural diagram of another display panel, in accordance with an embodiment of the disclosure;

FIG. 25 is a top view of the relative positions of a plurality of reflective units and light-emitting units in another display panel, in accordance with an embodiment of the disclosure;

FIG. 26 is a schematic structural diagram of another display panel, in accordance with an embodiment of the disclosure;

FIG. 27 is a schematic structural diagram of another display panel, in accordance with an embodiment of the disclosure;

FIG. 28 is a top view of another display panel, in accordance with an embodiment of the disclosure;

FIG. 29 is a schematic structural diagram of another display panel, in accordance with an embodiment of the disclosure;

FIG. 30 is a schematic structural diagram of another display panel, in accordance with an embodiment of the disclosure;

FIG. 31 is a schematic structural diagram of another display panel, in accordance with an embodiment of the disclosure;

FIG. 32 is a schematic structural diagram of another display panel, in accordance with an embodiment of the disclosure; and

FIG. 33 is a schematic structural diagram of another display panel, in accordance with an embodiment of the disclosure.

### DETAILED DESCRIPTION

The embodiments in the present disclosure will be clearly and thoroughly described hereinafter in combination with the accompanying drawings. Obviously, the described embodiments are merely part of the embodiments of the present disclosure, but not all of the embodiments. Based on the embodiments in the present disclosure, all other embodiments obtained by a person skilled in the art without making creative efforts are within the scope of protection of the present disclosure.

It is obvious to those skilled in the art that various modifications and variations may be made in this disclosure without departing from the spirit or scope of the disclosure. Therefore, the present disclosure is intended to cover modifications and variations of the disclosure that fall within the scope of the corresponding claims (technical solutions claimed for protection) and their equivalents. It should be noted that the embodiments provided in the embodiments of the disclosure may be combined with each other without conflict.

In order to make the objectives, features and advantages of the present disclosure more obvious and easier to understand, the present disclosure is further described in detail below in conjunction with the accompanying drawings and specific embodiments.

As described in the background technology section, since the luminous efficiency of micro-LED drops sharply as its size decreases, it is difficult for micro-LED display products to strike a balance between high resolution and high brightness display.

This is because if the micro-LED display is to achieve high resolution, the size of the micro-LED must be made small. When the size of the micro-LED is reduced to the micron level, the roughness of the micro-LED surface increases significantly relative to the area of the micro-LED, resulting in increased reflection and scattering inside the micro-LED, thereby reducing the light extraction efficiency of the micro-LED display, making the high-brightness display of the micro-LED display a bottleneck.

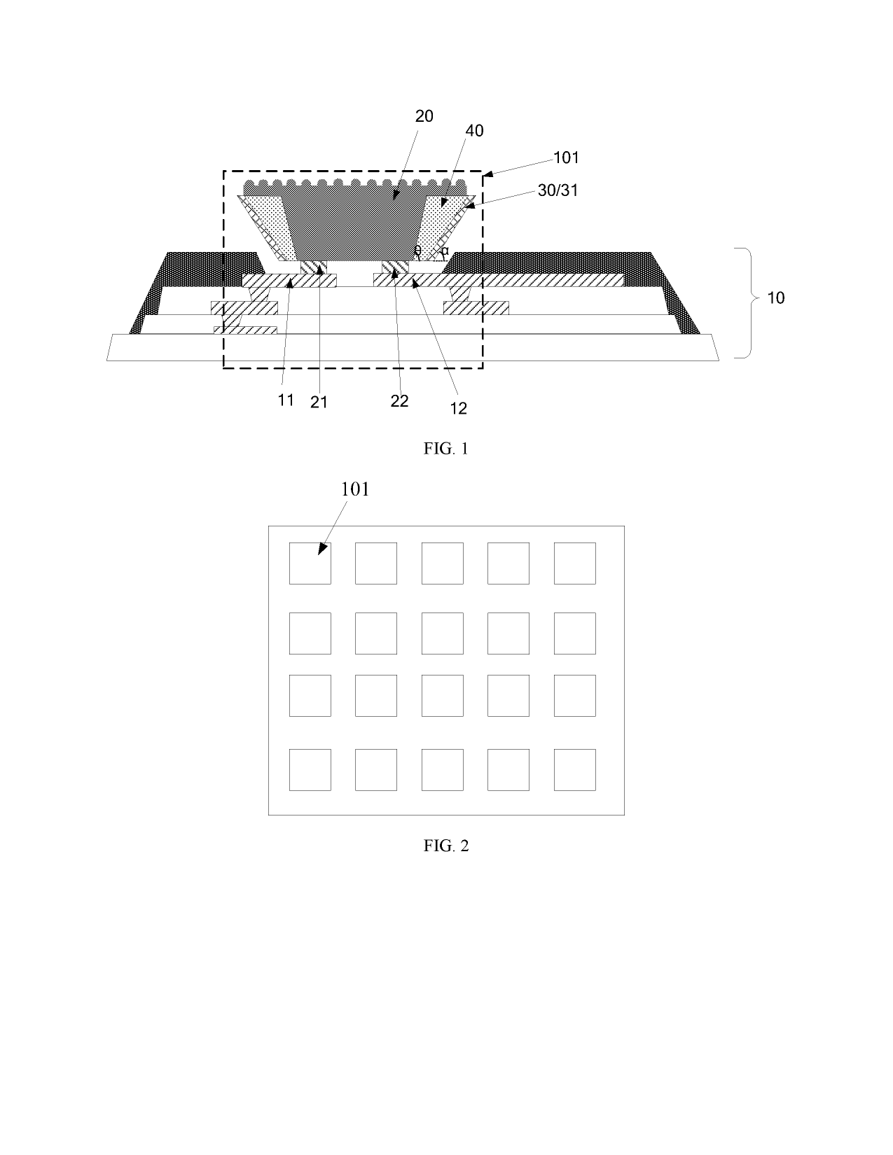

In view of the foregoing, an embodiment of the present disclosure provides a display panel. As shown in FIG. 1, the display panel includes: an array substrate 10; a plurality of light-emitting units 20 and a plurality of reflective units 30 located on a first side of the array substrate 10, where a reflective unit 30 includes a first reflective portion 31, and the first reflective portion 31 is located on at least one side surface of the corresponding light-emitting unit 20, and reflects light emitted from at least one side surface of the corresponding light-emitting unit 20 to the display side of the display panel; and a transparent portion 40 located on the first side of the array substrate 10, where at least a part of the transparent portion 40 is located between the first reflective portion 31 and the light-emitting unit 20.

Optionally, in one embodiment, the light-emitting unit is a micro-LED, but the present disclosure is not limited thereto, and it depends on the specific situation. The following takes micro-LED as a light-emitting unit as an example to describe the display panel provided by the embodiments of the present disclosure.

Specifically, in one embodiment, as shown in FIG. 1, the light-emitting unit 20 has a third electrode 21 and a fourth electrode 22, and the surface of the array substrate 10 has a first electrode 11 and a second electrode 12. The first electrode 11 is electrically connected to the third electrode 21 and is used to electrically connect the light-emitting unit 20 with a signal line in the array substrate 10 and provide a first voltage signal to the light-emitting unit 20. The second electrode 12 is electrically connected to the fourth electrode 22 and is used to electrically connect the light-emitting unit 20 and a signal line in the array substrate 10 and provide a second voltage signal to the light-emitting unit 20. The light-emitting unit 20 emits light under the control of the first voltage signal and the second voltage signal. It should be noted that the first electrode 11 and the third electrode 21 may be connected through a connection structure (not shown in the figure), and the connection structure may be a multi-layer metal structure or a conductive gold ball, etc.

In the display panel provided by the embodiments of the present disclosure, besides light-emitting units, reflective units are also provided. A reflective unit includes a first reflective portion, which is located on at least one side surface of the corresponding light-emitting unit, and reflects light emitted from at least one side surface of the corresponding light-emitting unit to the display side of the display panel, so that the light emitted from at least one side surface of the light-emitting unit is further emitted from an area above where the light-emitting unit is located. This thus improves the light extraction efficiency of the light-emitting unit, thereby improving the luminous efficiency of the light-emitting unit under the premise that the size of the light-emitting unit is fixed, so as to improve the display brightness of the display panel under a same driving signal when applied to a high-resolution display panel, and alleviate the problem of difficult balance between high resolution and high-brightness display of display products.

It should be noted that, in the present disclosure, the display panel further includes a transparent portion 40, which is located on the first side of the array substrate 10, and at least part of the transparent portion 40 is located between the first reflective portion 31 and the light-emitting unit 20, so that there is a certain distance between the light-emitting unit 20 and the first reflective portion 31. Accordingly, light emitted from at least one side surface of the light-emitting unit 20 may pass through the transparent portion 40, hit the first reflective portion, be reflected by the first reflective portion, and then pass through the transparent portion 40 to be emitted from the light-emitting side of the light-emitting unit 20. In this process, part of the light will also be emitted from the side of the transparent portion 40 away from the array substrate, thereby increasing the light emission area of the light-emitting region corresponding to each light-emitting unit 20.

Moreover, the light-emitting area corresponding to each light-emitting unit 20 will inevitably have edge effects when emitting light. That is, when the light-emitting area corresponding to each light-emitting unit 20 emits light, it is difficult to make the light emission amount in the edge areas and the light emission amount in the central area completely consistent. In the disclosed embodiment, a transparent portion 40 is further provided between the light-emitting unit 20 and the first reflective portion 31, so that the edge effect areas of each light-emitting area may be located in the area where the transparent portion 40 is located, thereby improving the light uniformity of the light emission area directly above each light-emitting unit 20, thereby improving the display brightness uniformity of the display panel.

It should also be noted that, in the disclosed embodiment, the reflective unit may be a reflective unit made of an insulating material, such as a Bragg reflective layer, or a reflective unit made of a conductive material, such as a metal reflective unit. When at least part of a transparent portion is provided between the reflective unit and the light-emitting unit, when the reflective unit is a conductive reflective unit, electrical insulation between the reflective unit and the light-emitting unit may be ensured, thereby reducing the probability of a short circuit in the light-emitting unit.

Moreover, the angle θ between the side surface of the light-emitting unit 20 and the array substrate 10 is relatively large, as shown in FIG. 1. That is, the side surface of the light-emitting unit 20 is relatively steep. If the first reflective portion 31 is directly formed on the side surface of the light-emitting unit 20, the process difficulty of the first reflective portion 31 will be significantly increased. In the disclosed embodiment, a transparent portion 40 is added between the light-emitting unit 20 and the first reflective portion 31. By setting a certain angle of the side surface of the transparent portion 40, the angle between the first reflective portion 31 and the plane where the array substrate 10 is located becomes smaller, thereby reducing the process difficulty of the first reflective portion 31, so that the first reflective portion 31 may better reflect the light emitted from the side surface of the light-emitting unit 20, thereby improving the light extraction efficiency of the light-emitting unit 20 and improving the display brightness of the display panel.

In addition, the angle θ between the side surface of the light-emitting unit 20 and the array substrate 10 is relatively large, and the light reflected by the first reflective portion 31 is directly incident on the side surface of the light-emitting unit 20 and is easily refracted to form a large-angle outgoing light (that is, the angle between the outgoing direction of the light and the direction perpendicular to the plane where the array substrate 10 is located is relatively small). In the disclosed embodiment, a transparent portion 40 is provided between the light-emitting unit 20 and the first reflective portion 31. By properly setting the angle between the transparent portion 40 and the plane where the array substrate 10 is located and the refractive index of the transparent portion 40, the emission angle of the light formed by the light reflected by the first reflective portion 31 and further refracted by the side of the light-emitting unit 20 is reduced. That is, the angle between the exit direction of the light formed by the light reflected by the first reflective portion 31 and the light exit direction of the light-emitting unit 20 (that is, the direction perpendicular to the plane where the array substrate 10 is located) is reduced. Accordingly, the light reflected by the first reflective portion 31 is emitted from directly above the light-emitting unit 20 as much as possible, thereby improving the light extraction efficiency of the light-emitting unit 20. When applied to a high-resolution display panel, under the same driving signal, the display brightness of the display panel is then improved, and the problem of the difficulty in balancing the high-resolution and high-brightness display of the display product is alleviated.

On the basis of the above embodiments, in one embodiment, the first reflective portion may be located on one side surface of the corresponding light-emitting unit, so that at least part of the light emitted from one side surface of the light-emitting unit is emitted from above the area where the light-emitting unit is located, thereby improving the light extraction efficiency of the light-emitting unit. The first reflective portion may also be located on at least two side surfaces of the corresponding light-emitting unit, so that at least part of the light emitted from at least two side surfaces of the light-emitting unit is emitted from above the area where the light-emitting unit is located, thereby further improving the light extraction efficiency of the light-emitting unit. The first reflective portion may also be located on each side surface of the corresponding light-emitting unit. That is, the first reflective portion is arranged around the corresponding light-emitting unit, and reflects at least part of the light emitted from each side surface of the light-emitting unit to the display side of the display panel, thereby further improving the light extraction efficiency of the light-emitting unit. The present disclosure does not limit the way the first reflective portion is configured, depending on the specific situation. The light-emitting unit includes a side facing the array substrate and a side away from the array substrate, and a side surface of the light-emitting unit is located between the side of the light-emitting unit facing the array substrate and the side away from the array substrate.

Optionally, in one embodiment, as shown in FIG. 1, the angle α formed between the plane where the first reflective portion 31 is located and the surface of the light-emitting unit 20 facing the array substrate 10 has a value in the range of 15° to 45°, so as to improve the reflection performance of the first reflective portion 31 to reflect the light emitted from the side surface of the light-emitting unit 20 to the light-emitting side of the light-emitting unit 20, thereby further improving the light extraction efficiency of the light-emitting unit 20. The specific value of angle α is not limited in the present disclosure, and it depends on the specific situation.

Optionally, in one embodiment, as shown in FIG. 1, the transparent portion 40 and the side surface of the light-emitting unit 20 are in direct contact, so as to reduce the gap between the transparent portion 40 and the light-emitting unit 20 in a direction parallel to the plane where the array substrate 10 is located, and reduce the size of the whole part composed of the light-emitting unit 20 and the transparent portion 40 in the direction parallel to the plane where the array substrate 10 is located. This is conducive to setting more light-emitting units 20 on the first side of the array substrate 10 under the premise that the area of the array substrate 10 is fixed, thereby facilitating the improvement of the resolution of the display panel. However, the present disclosure is not limited thereto, and in other embodiments of the present disclosure, the transparent portion 40 and the side surface of the light-emitting unit 20 may not be in direct contact, depending on the specific situation.

Optionally, in one embodiment, as shown in FIG. 1, the transparent portion 40 is in direct contact with the reflective unit 30. That is, the side of the transparent portion 40 away from the light-emitting unit 20 is in direct contact with the reflective unit 30, so as to reduce the gap between the transparent portion 40 and the reflective unit 30 in the direction parallel to the plane where the array substrate 10 is located, and reduce the size of the whole part composed of the reflective unit 30 and the transparent portion 40 in the direction parallel to the plane where the array substrate 10 is located. This is also conducive to setting more light-emitting units 20 on the first side of the array substrate 10 under the premise that the area of the array substrate 10 is fixed, thereby facilitating improvement in the resolution of the display panel. However, the present disclosure is not limited thereto, and in other embodiments of the present disclosure, the side surface of the transparent portion 40 and the reflective unit 30 may not be in direct contact, depending on the specific situation.

In one embodiment of the present disclosure, as shown in FIG. 1, the transparent portion 40 is in direct contact with the side surface of the light-emitting unit 20, and the transparent portion 40 is in direct contact with the reflective unit 30, so as to reduce the gap between the light-emitting unit 20 and the transparent portion 40 and the gap between the transparent portion 40 and the reflective unit 30 in a direction parallel to the plane where the array substrate 10 is located, and reduce the size of the whole part composed of the light-emitting unit 20, the reflective unit 30 and the transparent portion 40 in a direction parallel to the plane where the array substrate 10 is located. This is conducive to setting more light-emitting units 20 on the first side of the array substrate 10 under the premise that the area of the array substrate 10 is fixed, thereby facilitating improving the resolution of the display panel.

On the basis of the above embodiments, in one embodiment, as shown in FIGS. 1 and 2, the display panel includes a plurality of light-emitting areas 101, and each light-emitting area 101 is provided with a light-emitting element. Optionally, in one embodiment, the light-emitting element includes a light-emitting unit 20 and a first reflective portion 31. That is, in the disclosed embodiment, the light-emitting unit 20 and the first reflective portion 31 are both components of a light-emitting element.

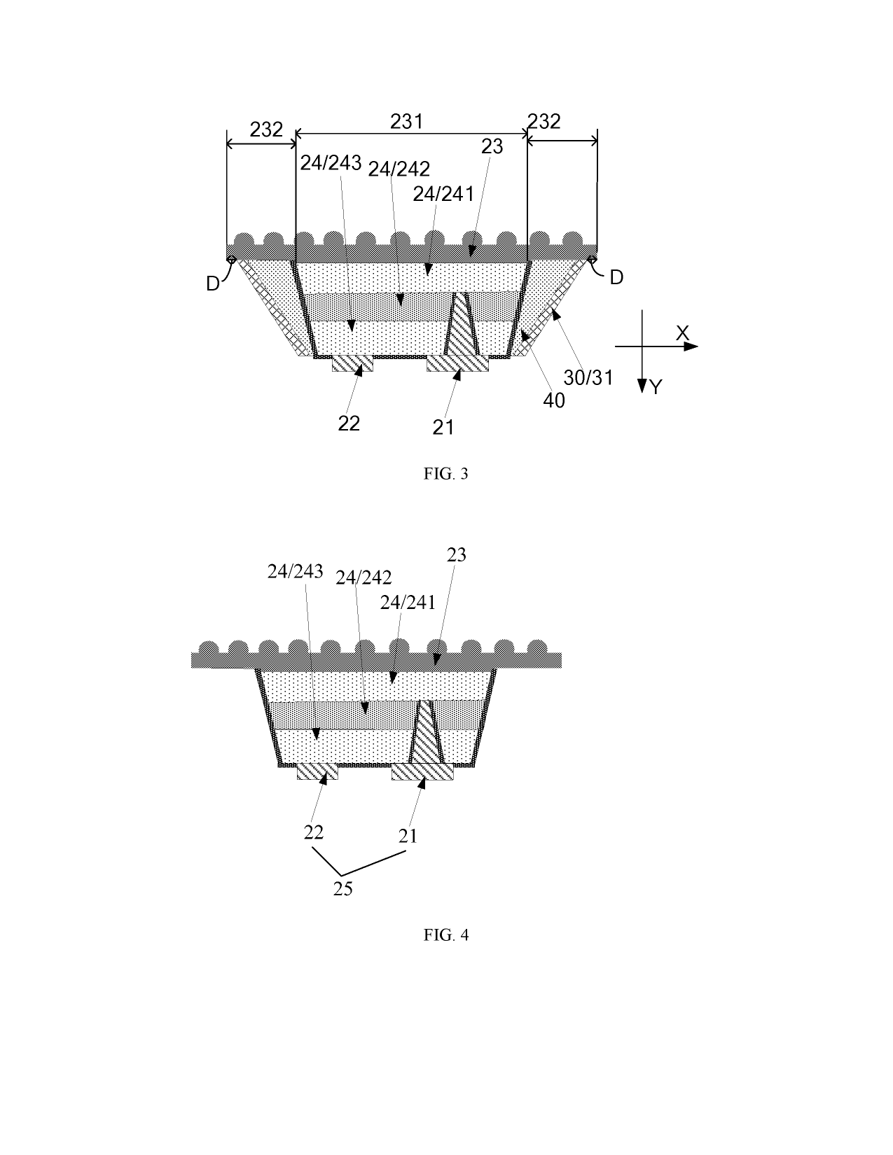

Optionally, in one embodiment, as shown in FIG. 3, the light-emitting unit 20 includes a buffer layer 23 and a light-emitting portion 24 located on one side of the buffer layer 23, where the buffer layer 23 includes a first region 231 and a second region 232 at least partially surrounding the first region 231. The light-emitting portion 24 is located in the first region 231, and the first reflective portion 31 is located in the second region 232. That is, the buffer layer 23 has an eaves-like structure relative to the light-emitting portion 24, namely, the light-emitting unit 20 adopts an eaves-like structure. Specifically, the light-emitting portion 24 includes a stacked N-type semiconductor layer 241 and a P-type semiconductor layer 243, and a quantum well layer 242 located between the N-type semiconductor layer 241 and the P-type semiconductor layer 243. In the disclosed embodiment, the light-emitting portion 24 is located in the first region 231, and the first reflective portion 31 is located in the second region 232. The first reflective portion 31 may be provided on the side of the light-emitting portion 24 to reflect at least part of the light emitted from the side surface of the light-emitting portion 24 to the top of the light-emitting portion 24, and to be emitted from the top of the light-emitting portion 24 (i.e., the side of the light-emitting portion away from the array substrate), thereby improving the light extraction efficiency of the light-emitting unit 20. This then improves the light-emitting efficiency of the light-emitting unit 20 under the same size and the same driving signal, and further improves the display brightness of the display panel.

It should be noted that, in the disclosed embodiment, the light-emitting portion is located in the first region of the buffer layer, the first reflective portion is located in the second region of the buffer layer, and the second region at least partially surrounds the first region, so that the light-emitting portion and the first reflective portion may be an integral structure. In the manufacturing process of the display panel, when the light-emitting unit is transferred to the array substrate, the second region of the buffer layer is conducive to the self-alignment between the light-emitting unit and the array substrate, thereby reducing the transfer alignment deviation in the process of transferring the light-emitting unit to the array substrate, so that the opening size on the array substrate for placing the light-emitting unit is smaller. Under the premise of the same size of the array substrate, it is conducive to placing more light-emitting units on the array substrate, which is conducive to improving the resolution of the display panel.

Optionally, based on the above embodiments, in one embodiment, as shown in FIG. 3, in a direction X parallel to the plane where the display panel is located, a distance D from the first reflective portion 31 to the second region 232 away from the first region 231 is greater than zero, so that in a direction Y perpendicular to the plane where the display panel is located, the buffer layer 23 covers the first reflective portion 31, so that in the process of transferring the light-emitting unit 20 to the array substrate 10, the transfer and alignment may be performed based on the size of the buffer layer 23, and the phenomenon that the first reflective portion 31 cannot be accommodated in the opening in the array substrate 10 when the transfer and positioning is performed based on the buffer layer 23 will not occur.

Optionally, in one embodiment, the first reflective portion is a Bragg reflective layer. In the disclosed embodiment, the manufacturing process of the display panel may include the following steps.

S101: As shown in FIG. 4, a light-emitting portion 24 is manufactured on the buffer layer 23, and the light-emitting portion 24 is etched so that the buffer layer 23 has an eaves-like structure relative to the light-emitting portion 24. Contact electrodes 25 (including a third electrode 21 and a fourth electrode 22) are formed on a surface of the light-emitting portion 24 away from the buffer layer 23 (i.e., an upper surface of the light-emitting portion 24), thereby forming a light-emitting unit.

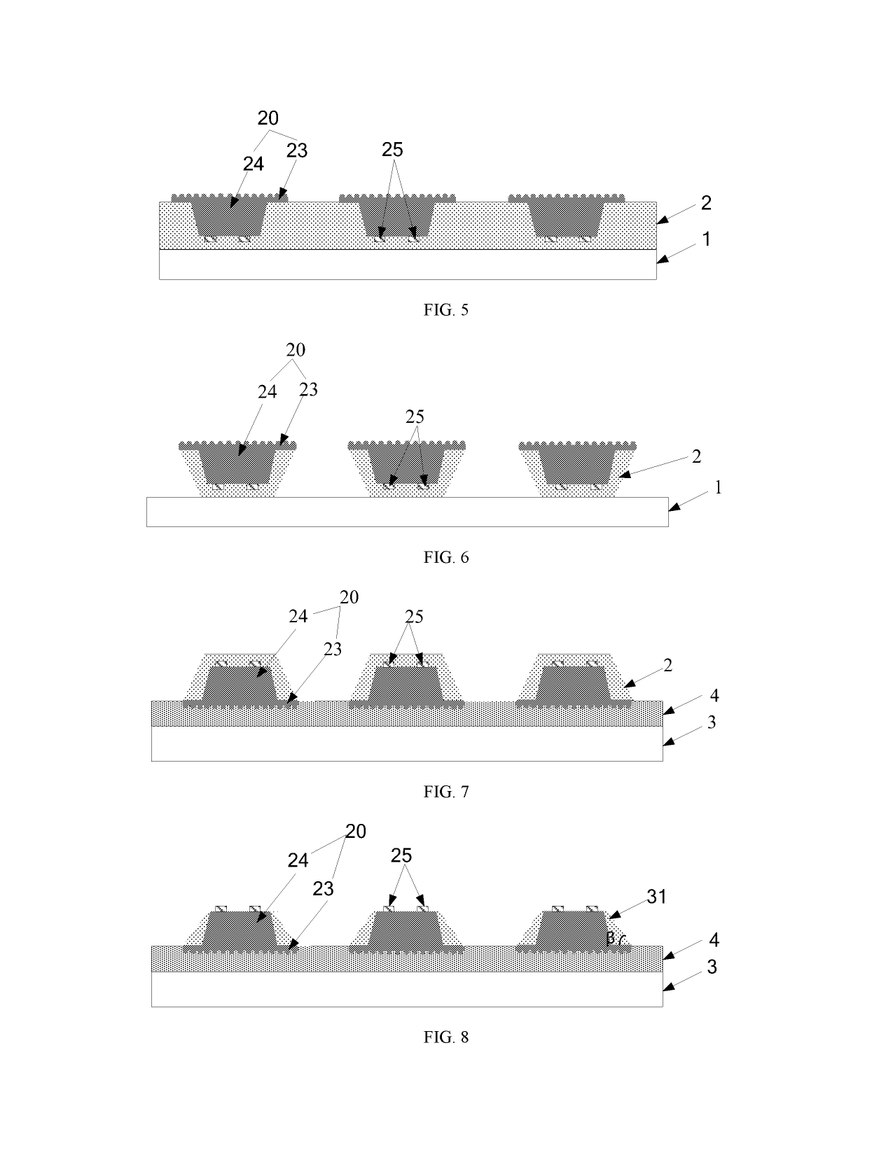

S102: As shown in FIG. 5, the light-emitting unit 20 is transferred onto the first substrate 1, a first adhesive layer 2 is provided between the first substrate 1 and the light-emitting unit 20 and between adjacent light-emitting units 20, and the light-emitting portion 24 is located between the buffer layer 23 and the first substrate 1.

S103: As shown in FIG. 6, a portion of the first adhesive layer 2 located between adjacent light-emitting units 20 is removed by a self-rotation process.

S104: As shown in FIG. 7, a side of the buffer layer 23 in the light-emitting unit 20 away from the light-emitting portion 24 is fixed to the second substrate 3, the surface of the second substrate 3 has a second adhesive layer 4, the second adhesive layer 4 is used to fix the light-emitting unit 20 and the second substrate 3, and the first substrate is removed, so as to transfer the light-emitting unit 20 from the first substrate to the second substrate 3.

S105: As shown in FIG. 8, the portion of the first adhesive layer 2 covering the upper surface of the light-emitting unit 20 is removed to expose the contact electrodes 25, and the portion of the first adhesive layer 2 located on the side of the light-emitting portion 24 in the light-emitting unit 20 is modified so that the angle β formed by the portion of the first adhesive layer 2 located on the side of the light-emitting portion 24 and the buffer layer 23 is less than 90°, such as the angle β formed by the portion of the first adhesive layer 2 located on the side of the light-emitting portion 24 and the buffer layer 23 is within a range of 15° to 45°.

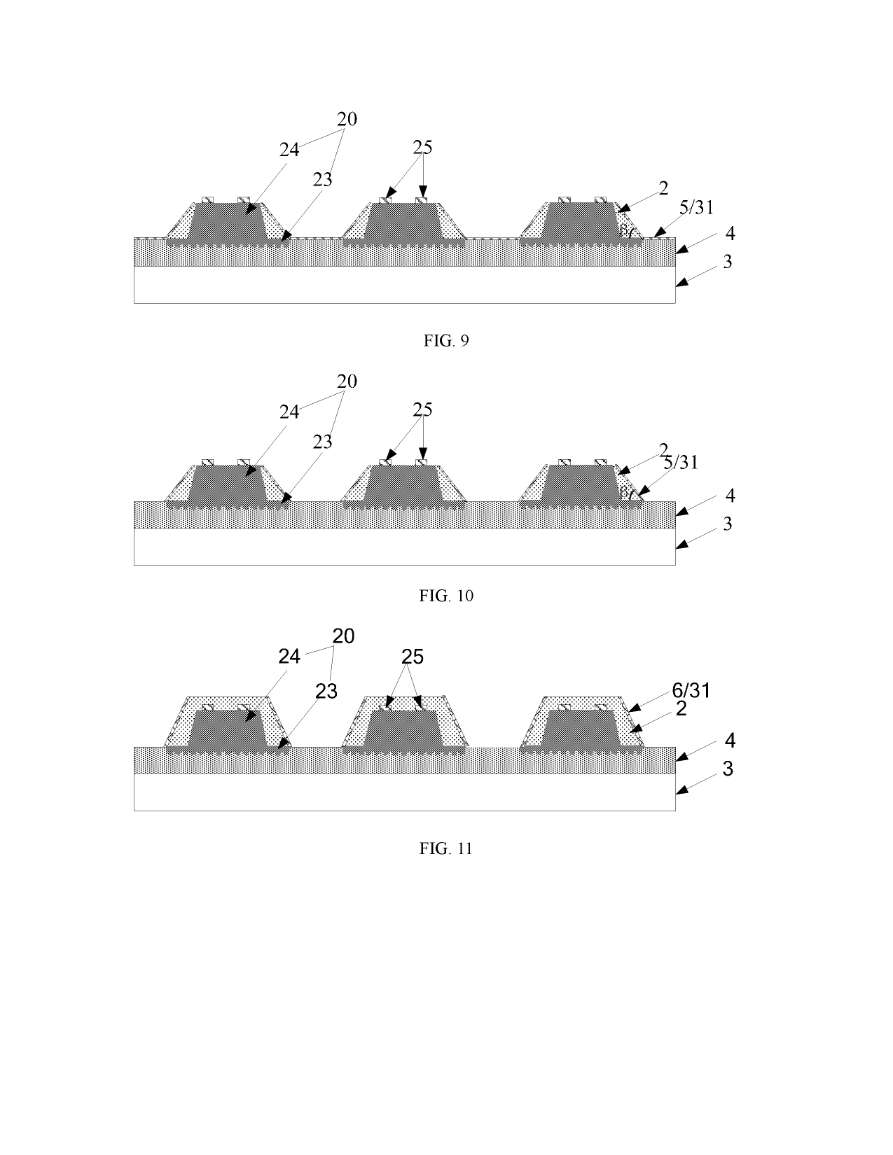

S106: As shown in FIG. 9, a Bragg reflective layer 5 covering the contact electrodes 25 and the first adhesive layer 2 is formed, and the Bragg reflective layer 5 is etched to expose the contact electrodes 25. A first reflective portion 31 is formed on at least one side surface of the light-emitting portion 24. It should be noted that, in the disclosed embodiment, the first reflective portion 31 may extend to cover the area between adjacent light-emitting units, as shown in FIG. 9, so as to simplify the process flow of the first reflective portion 31, but the present disclosure is not limited thereto. In other embodiments of the present disclosure, the first reflective portion 31 may not cover the area between adjacent light-emitting units 20, as shown in FIG. 10, depending on the specific situation.

S107: As shown in FIG. 1, the contact electrodes 25 (including the third electrode 21 and the fourth electrode 22) in the light-emitting unit 20 are fixed to the array substrate 10, and the second substrate 3 and the second adhesive layer 4 are removed to transfer the light-emitting unit 20 from the second substrate 3 to the array substrate 10.

In another embodiment of the present disclosure, the first reflective portion is a metal reflective layer. In the disclosed embodiment, the manufacturing process of the display panel may include the following.

S201- S204: The contents of S201-S204 are the same as S101-S104, and will not be repeated here.

S205: As shown in FIG. 11, a metal reflective layer 6 is formed on the surface of the first adhesive layer 2, and the metal reflective layer 6 is patterned to expose a portion of the first adhesive layer 2 located on the upper surface of the light-emitting portion 24.

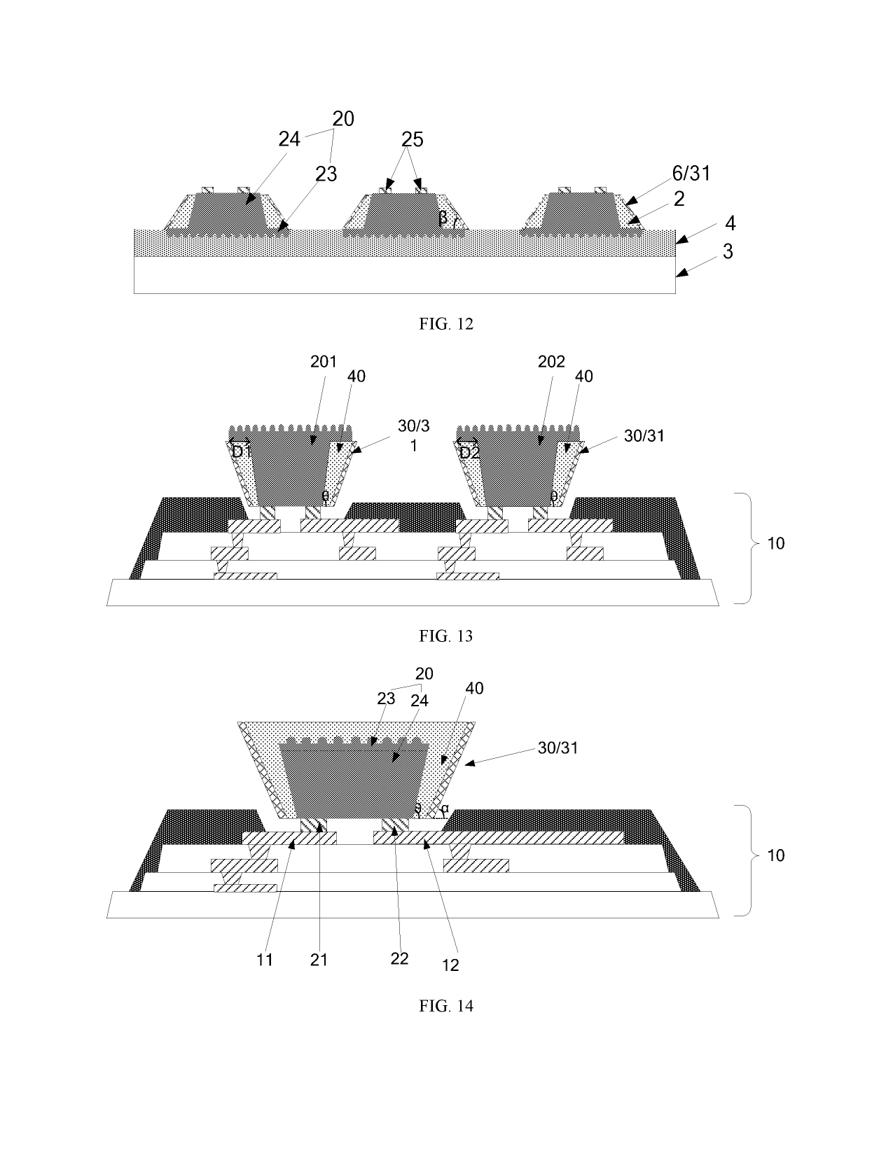

S206: As shown in FIG. 12, the portion of the first adhesive layer 2 covering the upper surface of the light-emitting portion 24 is removed to expose the contact electrodes 25.

S207: As shown in FIG. 12, the portion of the metal reflective layer 6 located on the side of the first adhesive layer 2 is modified so that the angle β formed by the portion of the metal reflective layer 6 located on the side of the first adhesive layer 2 and the buffer layer 23 is less than 90°, for example, the angle β formed by the portion of the metal reflective layer 6 located on the side of the light-emitting portion 24 and the buffer layer 23 is within a range of 15° to 45°.

S208: As shown in FIG. 1, the contact electrodes 25 in the light-emitting unit 20 are fixed to the array substrate 10, and the second substrate 3 and the second adhesive layer 4 are removed to transfer the light-emitting unit 20 from the second substrate 3 to the array substrate 10.

It should be noted that, in the above embodiment, the first adhesive layer is made of a transparent material, and the portion of the first adhesive layer located between the light-emitting unit and the first reflective portion is a transparent portion.

It should also be noted that, compared with the manufacturing method of forming the first reflective portion using a metal reflective layer, the manufacturing method of forming the first reflective portion using a Bragg reflective layer in the previous embodiment may modify the angle formed between the first adhesive layer and the buffer layer, thereby facilitating better control of the angle formed between the first reflective portion and the buffer layer. This further facilitates better reflection of the light emitted from the side of the reflective light-emitting portion to the light-emitting side of the light-emitting unit, thereby improving the light extraction efficiency of the light-emitting unit and improving the display brightness of the display panel.

Optionally, in one embodiment, the buffer layer is a gallium nitride buffer layer. In the disclosed embodiment, producing a light-emitting portion on the buffer layer includes directly producing the light-emitting portion on the gallium nitride buffer layer. In another embodiment of the present disclosure, the buffer layer is another inorganic film buffer layer. In the disclosed embodiment, producing the light-emitting portion on the buffer layer includes: producing the light-emitting portion on the gallium nitride buffer layer; fixing the side of the light-emitting portion away from the gallium nitride buffer layer on a third substrate; removing the gallium nitride buffer layer; forming an inorganic film buffer layer of other materials on the upper surface and side of the light-emitting portion, and removing the portion of the inorganic film buffer layer located on the side of the light-emitting portion, so that the inorganic film buffer layer has an eaves-like structure relative to the light-emitting portion.

On the basis of the above embodiments, in one embodiment, as shown in FIG. 13, the display panel includes: a first type of light-emitting unit 201 and a second type of light-emitting unit 202, where the first type of light-emitting unit 201 and the second type of light-emitting unit 202 are light-emitting units of different colors. Optionally, in the disclosed embodiment, in a plane parallel to the array substrate 10, the second region of the first type of light-emitting unit 201 has a first width D1, and the second region of the second type of light-emitting unit 202 has a second width D2. It should be noted that under the same driving signal, the light luminance of light-emitting units of different colors is different. Therefore, in one embodiment of the present disclosure, the first width D1 and the second width D2 are different, so that the light loss on the optical path between the first type of light-emitting unit and its corresponding first reflective portion is different from the light loss on the optical path between the second type of light-emitting unit and its corresponding second reflective portion. The light extraction efficiency of the first type of light-emitting unit improved by the amount of light reflected back by the first reflective portion corresponding to the first type of light-emitting unit and the light extraction efficiency of the second type of light-emitting unit improved by the amount of light reflected back by the second reflective portion corresponding to the second type of light-emitting unit are thus different, thereby balancing the light luminance of the first type of light-emitting unit and the second type of light-emitting unit under the same driving signal. Optionally, the first type of light-emitting unit 201 is a red light-emitting unit, and the second type of light-emitting unit is a blue light-emitting unit or a green light-emitting unit, where D1 is smaller than D2.

It should be noted that the above embodiments are described by taking the example that the buffer layer has an eaves-like structure compared to the light-emitting portion, but the present disclosure is not limited thereto. In other embodiments of the present disclosure, the buffer layer may not have an eaves-like structure compared to the light-emitting portion, depending on the specific circumstances.

Optionally, in one embodiment, as shown in FIG. 14, the light-emitting unit 20 includes a buffer layer 23 and a light-emitting portion 24 located on the surface of the buffer layer 23, and the area of the surface of the light-emitting portion 24 facing the buffer layer 23 is the same as the area of the surface of the buffer layer 23 facing the light-emitting portion 24. In the disclosed embodiment, the buffer layer 23 does not have an eaves-like structure relative to the light-emitting portion 24.

It should be noted that compared with the buffer layer having an eaves-like structure relative to the light-emitting portion, for the buffer layer that does not have an eaves-like structure relative to the light-emitting portion, the light-emitting unit does not need to form an eaves-like structure, the process is relatively simple, and the area of a single light-emitting unit is smaller, which is conducive to placing more light-emitting units under the premise of the same array substrate area, which is conducive to improving the resolution of the display panel.

Compared with the buffer layer having no eaves-like structure relative to the light-emitting portion, for the buffer layer that has an eaves-like structure relative to the light-emitting portion, when the light-emitting unit is transferred to the array substrate, a self-rotation process may be adopted, and the process error introduced is relatively small.

On the basis of the above embodiments, in one embodiment, as shown in FIG. 14, the transparent portion 40 also covers the surface of the light-emitting unit 20 away from the array substrate 10. That is, the transparent portion 40 also covers the surface of the buffer layer 23 away from the light-emitting portion 24. In the disclosed embodiment, when the first reflective portion 31 is located on the side of the transparent portion 40, the height of the first reflective portion 31 may be greater than the height of the light-emitting unit 20, so that more light emitted from the light-emitting unit 20 not directly above the light-emitting unit 20 is reflected to be emitted directly above the light-emitting unit 20, thereby improving the light extraction efficiency of the light-emitting unit 20 and improving the display brightness of the display panel. Here, the height of the first reflective portion 31 is the height of the first reflective portion 31 in the direction perpendicular to the plane where the array substrate 10 is located, and the height of the light-emitting unit 20 is the height of the light-emitting unit in the direction perpendicular to the plane where the array substrate 10 is located. The height of the first reflective portion 31 is greater than the height of the light-emitting unit 20. That is, the surface of the first reflective portion 31 away from the array substrate 10 is higher than the surface of the light-emitting unit 20 away from the array substrate 10.

In addition, the transparent portion 40 also covers the surface of the light-emitting unit 20 away from the array substrate 10, and may also protect the surface of the light-emitting unit 20 away from the array substrate 10.

Optionally, in one embodiment, a method for manufacturing a display panel includes the following.

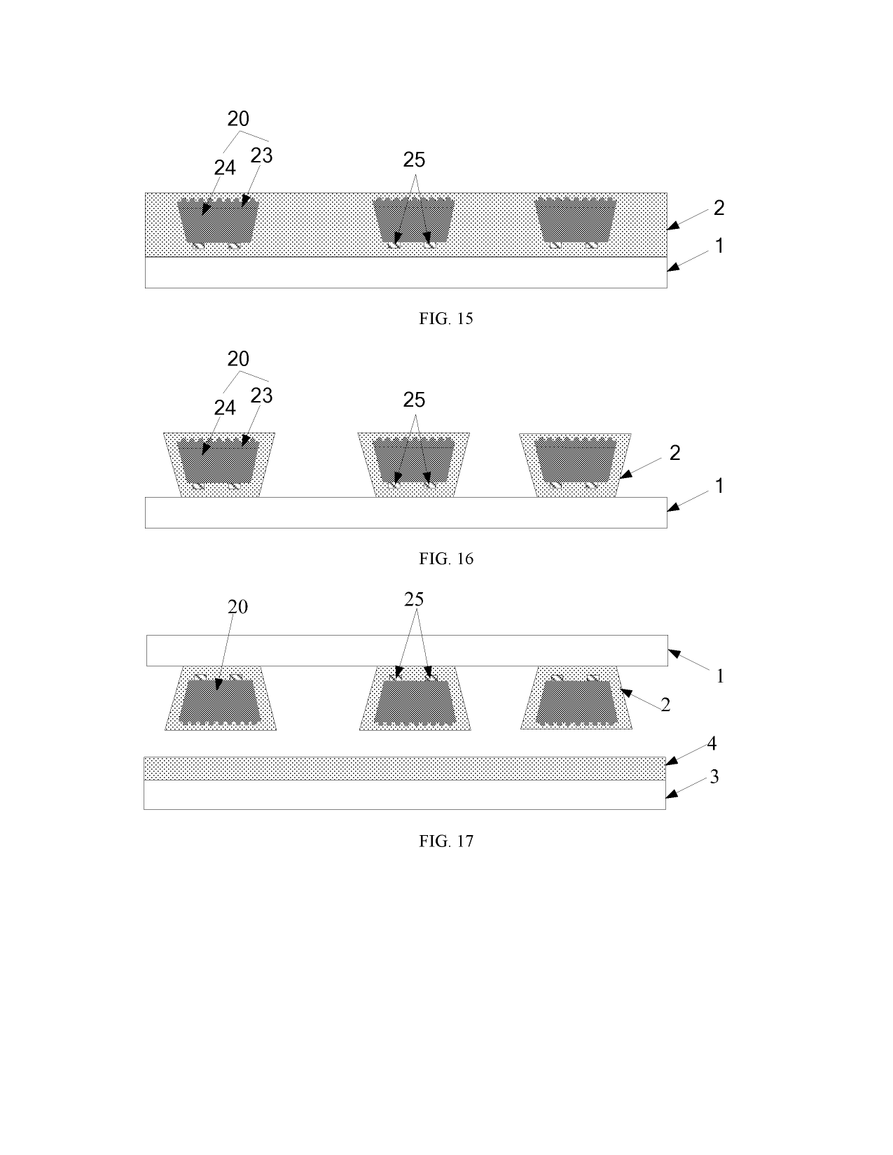

S301: As shown in FIG. 15, a light-emitting portion 24 is manufactured on the buffer layer 23, and contact electrodes 25 are formed on a surface of the light-emitting portion 24 away from the buffer layer 23 (i.e., an upper surface of the light-emitting portion 24), thereby forming a light-emitting unit 20.

S302: As shown in FIG. 15, the light-emitting unit 20 is transferred to the first substrate 1, a first adhesive layer 2 is provided between the first substrate 1 and the light-emitting unit 20 and between adjacent light-emitting units 20, the light-emitting portion 24 is located between the buffer layer 23 and the first substrate 1, and optionally, the first adhesive layer 2 also covers the surface of the light-emitting unit 20 on a side away from the array substrate 10.

S303: As shown in FIG. 16, a portion of the first adhesive layer 2 located between adjacent light-emitting units 20 is removed by a self-rotation process.

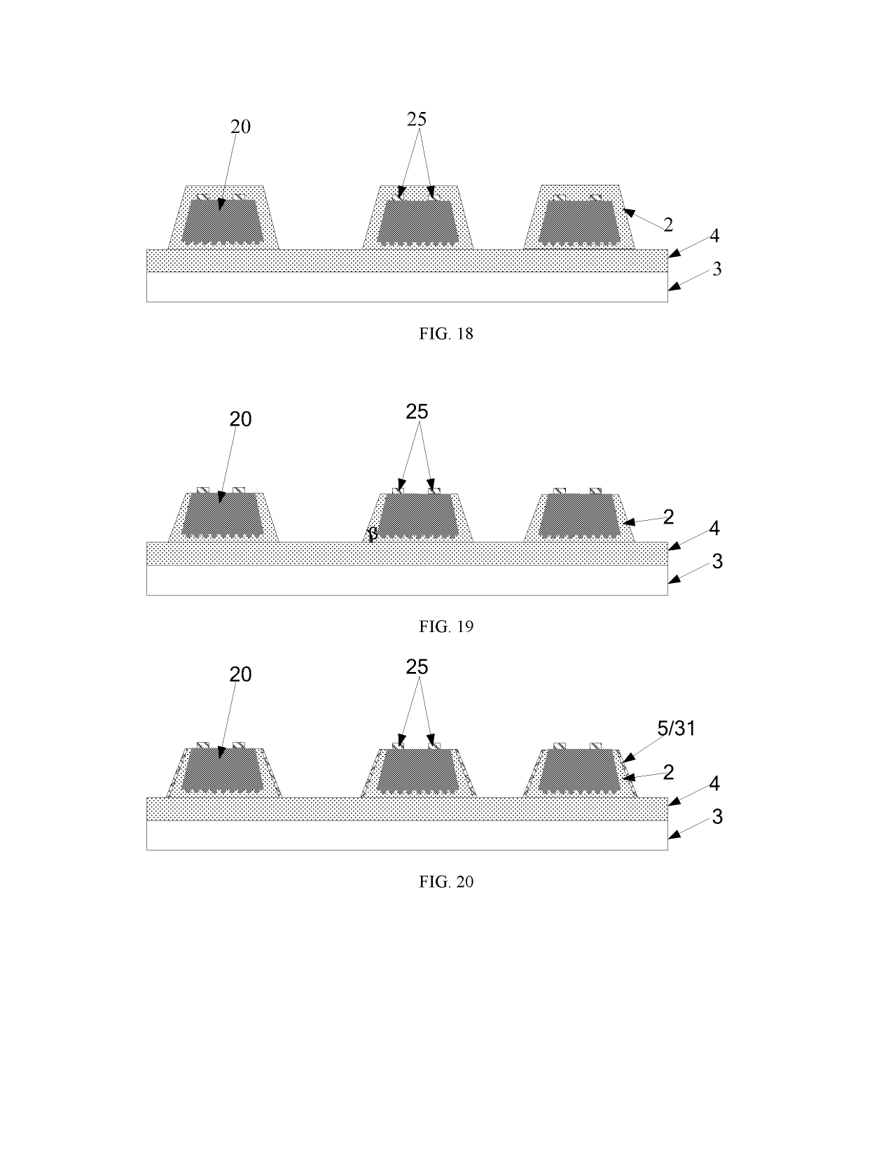

S304: As shown in FIGS. 17 and 18, a side of the buffer layer 23 in the light-emitting unit 20 away from the light-emitting portion 24 is fixed to the second substrate 3, the surface of the second substrate 3 has a second adhesive layer 4, the second adhesive layer 4 is used to fix the light-emitting unit 20 and the second substrate 3, and the first substrate 1 is removed, so as to transfer the light-emitting unit 20 from the first substrate to the second substrate 3.

S305: As shown in FIG. 19, the portion of the first adhesive layer 2 covering the upper surface of the light-emitting unit 20 is removed to expose the contact electrodes 25, and the portion of the first adhesive layer 2 located on the side of the light-emitting portion 24 in the light-emitting unit 20 is modified so that the angle β formed by the portion of the first adhesive layer 2 located on the side of the light-emitting portion 24 and the buffer layer 23 is less than 90°, such as the angle β formed by the portion of the first adhesive layer 2 located on the side of the light-emitting portion 24 and the buffer layer 23 is within a range of 15° to 45°.

S306: As shown in FIG. 20, a Bragg reflective layer 5 is formed to cover the contact electrodes 25 and the first adhesive layer 2, and the Bragg reflective layer 5 is etched to expose the contact electrodes 25, and a first reflective portion 31 is formed on at least one side surface of the light-emitting portion 24.

S307: As shown in FIG. 14, the contact electrodes 25 (including the third electrode 21 and the fourth electrode 22) in the light-emitting unit 20 are fixed to the array substrate 10, and the second substrate 3 and the second adhesive layer 4 are removed to transfer the light-emitting unit 20 from the second substrate 3 to the array substrate 10.

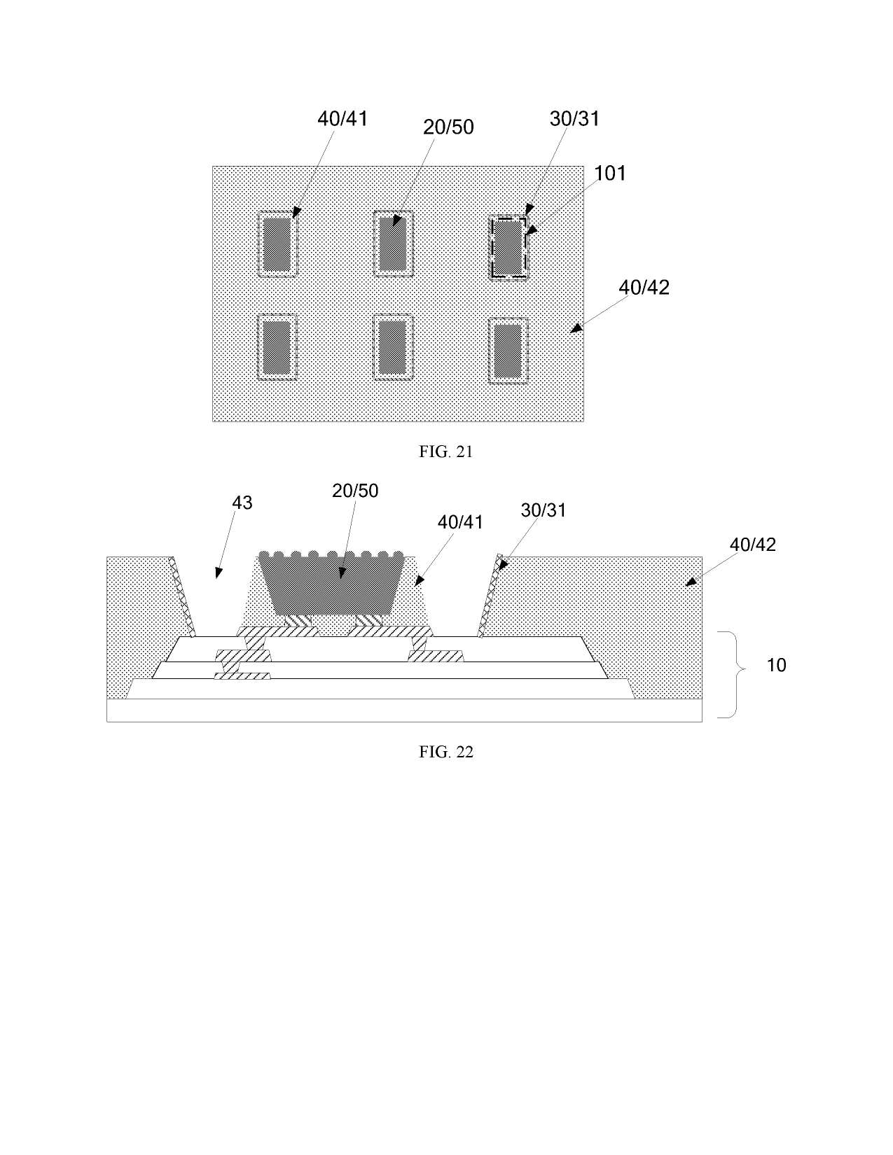

In another embodiment of the present disclosure, as shown in FIG. 21, the display panel includes a plurality of light-emitting areas 101, each light-emitting area 101 is provided with a light-emitting element 50, the light-emitting element 50 includes a light-emitting unit 20, a gap is provided between the first reflective portion 31 and the light-emitting element 50, and a transparent portion 40 is partially located between the first reflective portion 31 and the light-emitting element 50. It should be noted that, unlike the embodiment disclosed herein, in the previous embodiments, the first reflective portion 31 is a component of the light-emitting element 50, and is formed during the manufacturing process of the light-emitting element 50. In the present embodiment, the first reflective portion 31 is not a component of the light-emitting element 50, and is not formed during the manufacturing process of the light-emitting element 50, but is formed during the manufacturing process of the display panel. Therefore, the manufacturing of the display panel provided in the embodiment of the present disclosure does not require changing the manufacturing process of the light-emitting element 50, and is compatible with the existing process flow of manufacturing the light-emitting element.

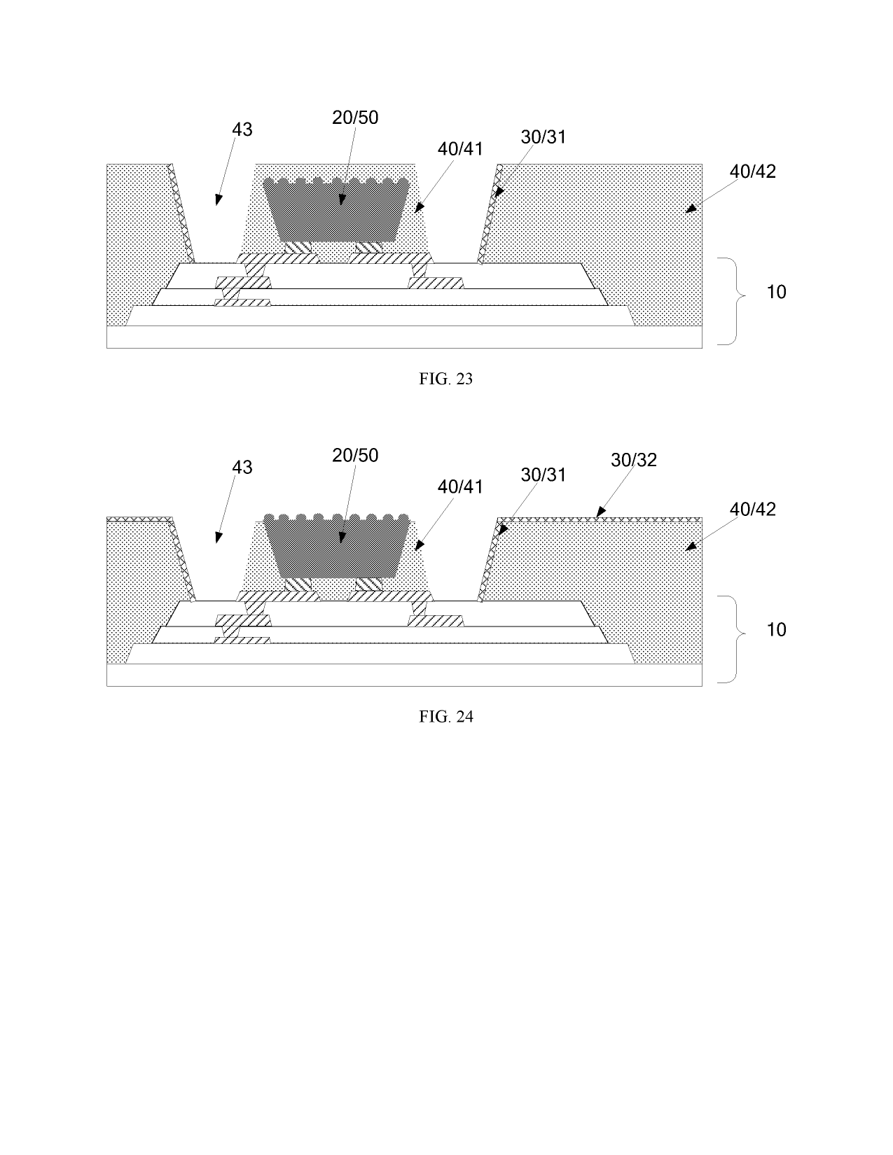

Optionally, in one embodiment, as shown in FIGS. 21 and 22, the transparent portion 40 at least covers the area between adjacent light-emitting elements 50, and exposes the light-emitting area of the light-emitting element 50 away from the array substrate 10, so that the setting of the transparent portion 40 does not affect the light emitted from the light-emitting area of the light-emitting element 50. However, the present disclosure is not limited thereto, and in other embodiments of the present disclosure, the transparent portion 40 may also cover the surface of the light-emitting unit 20 or the light-emitting element 50 away from the array substrate 10, as shown in FIG. 23, depending on the specific situation.

The display panel provided in the embodiments of the present disclosure is described below by taking an example in which a transparent portion exposes a light-emitting area of a light-emitting element away from the array substrate.

Specifically, in the disclosed embodiment, as shown in FIG. 22, the transparent portion 40 includes a first transparent portion 41 and a second transparent portion 42, where the first transparent portion 41 is located on the side of the light-emitting element 50, the second transparent portion 42 surrounds the first transparent portion 41, and a through hole 43 is provided between the second transparent portion 42 and the first transparent portion 41. The first reflective portion 31 is located in the through hole 43, so that the first transparent portion 41 is located between the first reflective portion 31 and the light-emitting element 50.

Optionally, in one embodiment, as shown in FIGS. 22 and 23, the transparent portion 40 may also fill the gap between the light-emitting element 50 and the array substrate 10, but the present disclosure is not limited thereto, and it depends on the specific circumstances.

Optionally, in one embodiment, as shown in FIGS. 22 and 23, the area of the through hole 43 away from the array substrate 10 is larger than the area of the through hole 43 close to the array substrate 10. For example, the through hole 43 is an inverted trapezoidal through hole. In the disclosed embodiment, the first reflective portion 31 is located on the side of the through hole 43 away from the light-emitting element 50, so that when the first reflective portion 31 is a metal reflective portion, the first reflective portion 31 is electrically insulated from the contact electrodes of the light-emitting element 50, thereby avoiding a short circuit with the third electrode 21 and the fourth electrode 22 of the light-emitting element 50. However, the present disclosure is not limited thereto. In other embodiments of the present disclosure, the first reflective portion may also be a Bragg reflective layer, depending on the specific situation.

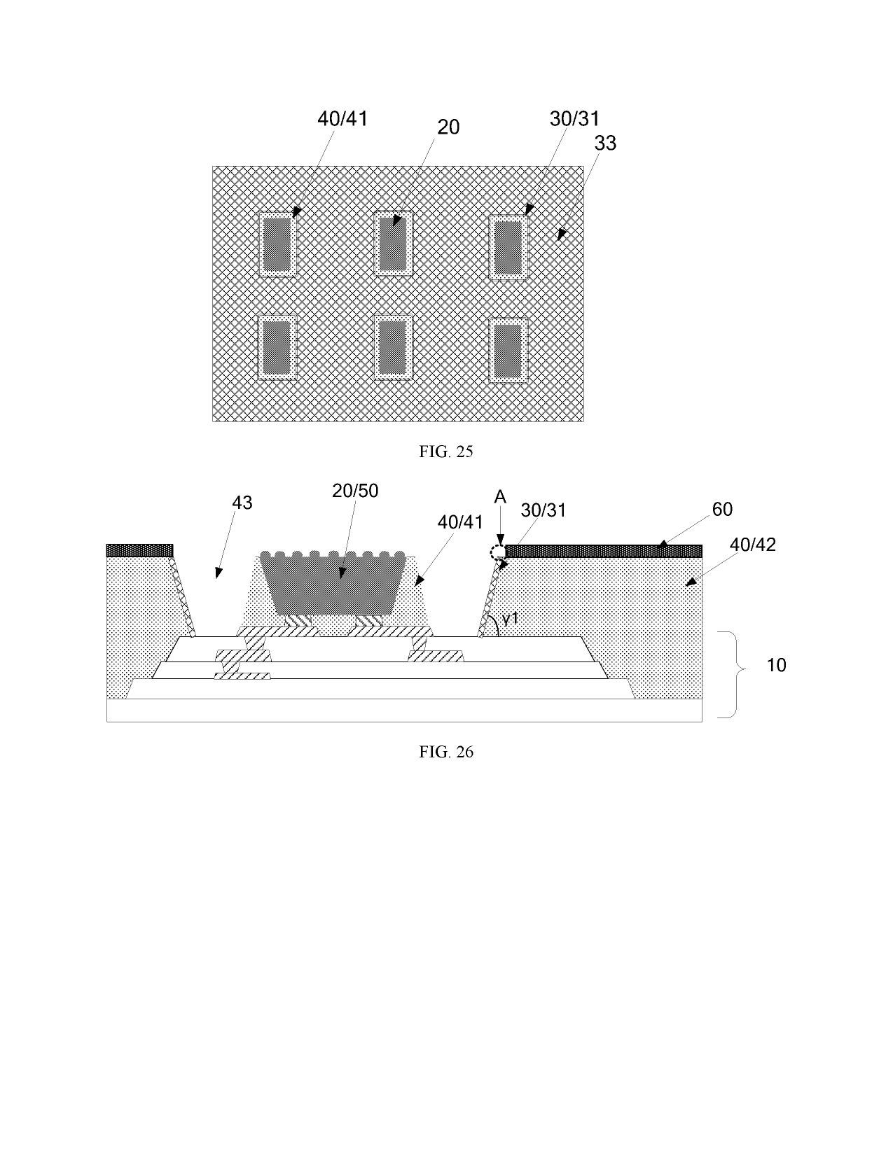

On the basis of the above embodiments, in one embodiment, the reflective unit 30 may be located merely on the side of the through hole 43 away from the light-emitting element 50, as shown in FIGS. 22 and 23, or may extend to cover the surface of the second transparent portion 42 away from the array substrate 10, as shown in FIG. 24, and the present disclosure is not limited thereto, depending on the specific circumstances. Specifically, in one embodiment, when the reflective unit 30 extends to cover the surface of the second transparent portion 42 away from the array substrate 10, the multiple reflective units 30 are different parts of the same reflective structure 33. That is, the multiple reflective units 30 are an integrated structure, as shown in FIG. 25, the integrated structure 33 composed of the multiple reflective units 30 has multiple holes, and the light-emitting elements 20 are located in the holes of the integrated structure 33, but the present disclosure is not limited thereto, depending on the specific circumstances.

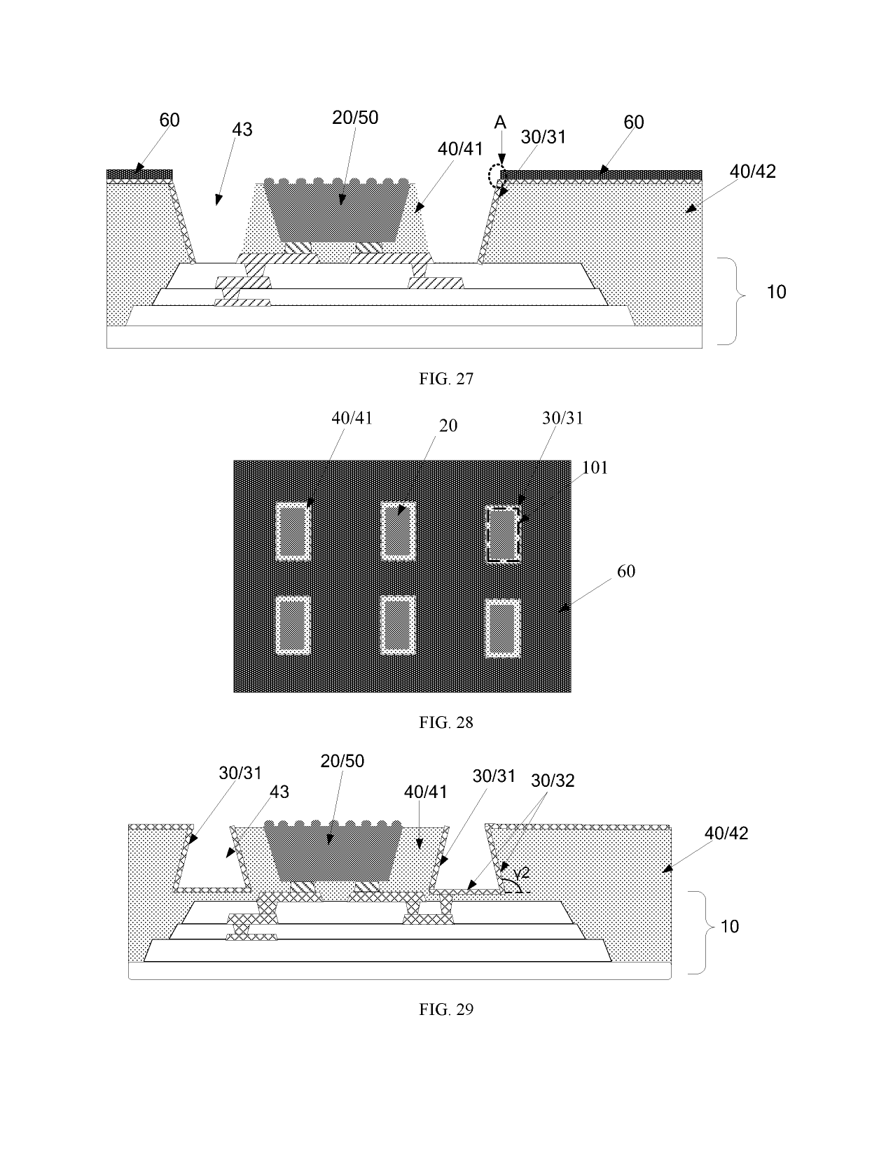

Optionally, in one embodiment, as shown in FIGS. 26 and 27, the display panel also includes a light-shielding unit 60, which covers a portion of the surface of the second transparent portion 42 (a top view thereof is shown in FIG. 28), so as to absorb ambient light that enters the interior of the display panel, thereby reducing light reflection on the display surface of the display panel and improving display quality.

On the basis of the above embodiments, in one embodiment, as shown in FIG. 26, the slope angle γ1 of the sidewall of the through hole 43 is less than 90°. Optionally, the slope angle γ1 of the sidewall of the through hole 43 is in the range of 15° to 45°. That is, the angle between the sidewall of the through hole 43 and the plane where the array substrate 10 is located is in the range of 15° to 45°, so as to reduce the process difficulty of the reflective unit 30, but the present disclosure is not limited thereto, and it depends on the specific situation.

In another embodiment of the present disclosure, as shown in FIG. 29, the area of the through hole 43 on the side away from the array substrate 10 is smaller than the area on the side close to the array substrate 10. That is, the through hole 43 is a trapezoidal through hole, and the first reflective portion 31 is located on the side of the through hole 43 close to the light-emitting element 20 to reduce the distance between the first reflective portion 31 and the light-emitting element 50, reduce the light loss on the optical path of the light-emitting unit 20 that is emitted from the side surface of the light-emitting unit 20 and hits the first reflective portion 31 and then is reflected back to the light-emitting unit 20 by the first reflective portion 31, thereby improving the light extraction efficiency of the light-emitting unit 20.

On the basis of the above embodiments, in one embodiment, the reflective unit 30 further includes a second reflective portion 32, and the second reflective portion 32 is located on the side of the through hole 43 away from the light-emitting element 50 and the bottom of the through hole 43 to reduce the process difficulty when manufacturing the reflective unit 30. Optionally, the reflective unit 30 also extends to cover the surface of the second transparent portion 42 away from the array substrate 10, but the present disclosure is not limited thereto, and it depends on the specific circumstances.

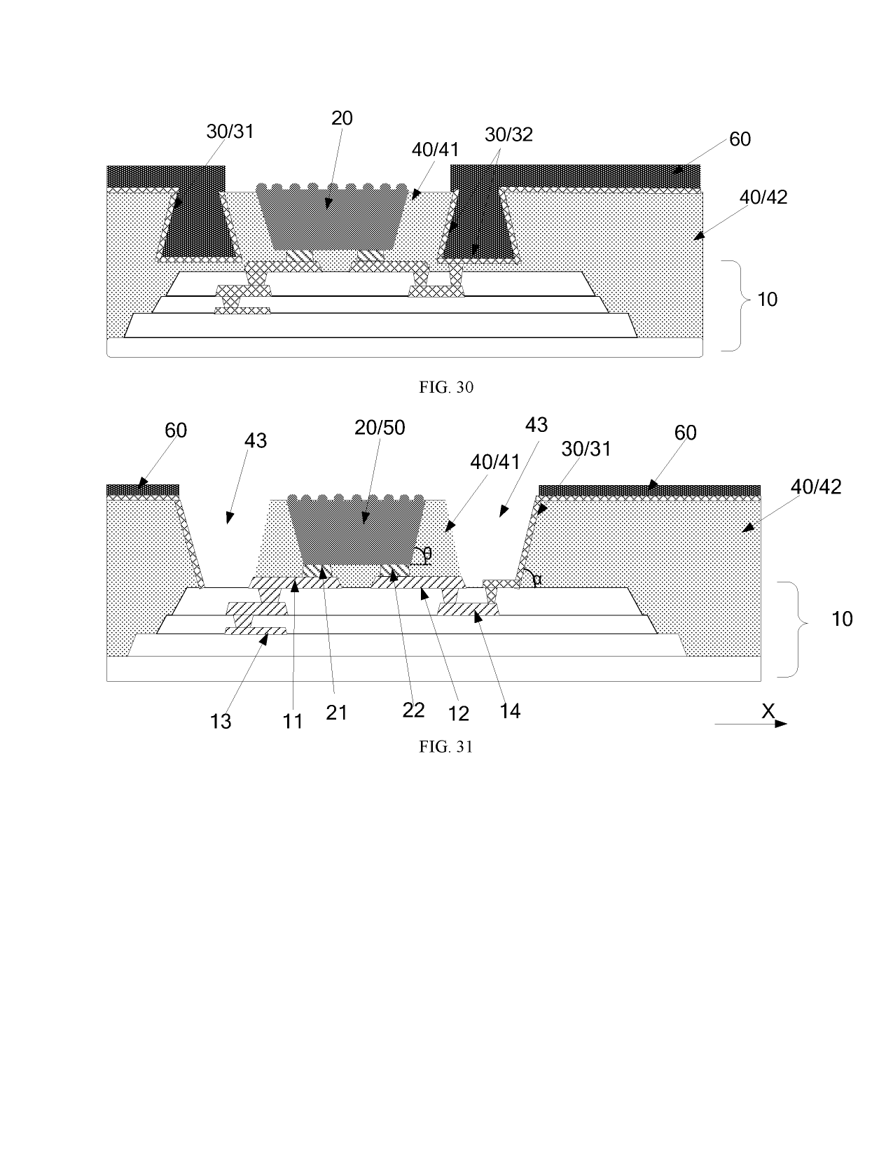

Optionally, in one embodiment, as shown in FIG. 30, the display panel also includes a light-shielding unit 60, which covers a portion of the surface of the second transparent portion 42 to absorb ambient light entering the interior of the display panel, thereby reducing light reflection on the display surface of the display panel and improving display quality.

It should be noted that during the etching process, the negative photoresist will automatically form an etched through hole that is narrow along the etching direction and wide at the bottom. Therefore, in one embodiment, the transparent portion is a negative photoresist layer, and the area of the through hole on the side away from the array substrate is smaller than the area on the side close to the array substrate, so as to reduce the process difficulty when forming the through hole in the transparent portion.

It should also be noted that, in the process of manufacturing the display panel, process errors are inevitably present in each process step, and due to the existence of process errors, the light-shielding unit 60 in the display panel shown in FIGS. 26 and 27 cannot completely cover the second transparent portion 42, as shown in the line frame A in FIGS. 26 and 27. In the display panel shown in FIG. 30, the portion of the light-shielding unit 60 located in the through hole 43 and the portion located on the surface of the second transparent portion 42 away from the array substrate 10 are integrated, and the second transparent portion 42 may be completely covered. Therefore, compared with the display panels shown in FIGS. 26 and 27, the display panel shown in FIG. 30 may better absorb the light from the environment incident into the display panel, which is beneficial to further improve the display quality of the display panel.

Based on the above embodiments, in one embodiment, as shown in FIG. 29, the slope angle γ2 of the sidewall of the through hole 43 is greater than 90°. Optionally, the slope angle γ2 of the sidewall of the through hole 43 is in the range of 115°~135° to reduce the process difficulty of the reflective unit 30, but the present disclosure is not limited thereto, and it depends on the specific situation.

Based on the above embodiments, in one embodiment, the first transparent portion 41 and the second transparent portion 42 are made of the same material, so that the first transparent portion and the second transparent portion may be manufactured at the same time, reducing the process flow of manufacturing the transparent portions, but the present disclosure is not limited thereto, and it depends on the specific situation.

On the basis of the above embodiments, in one embodiment, as shown in FIG. 31, the third electrode 21 is the positive electrode of the light-emitting unit 20, the fourth electrode 22 is the negative electrode of the light-emitting unit 20, the array substrate 10 includes a first electrode 11 and a second electrode 12 located on the surface of the array substrate 10. A first signal line 13 and a second signal line 14 are located inside the array substrate 10. The first signal line 13 is electrically connected to the positive electrode of the light-emitting unit 20 through the first electrode 11, and the second signal line 14 is electrically connected to the negative electrode of the light-emitting unit 20 through the second electrode 12. Optionally, in one embodiment, the first reflective portion 31 is electrically connected to the second signal line 14 to reduce the signal transmission impedance in the second signal line 14, and at the same time provide a heat dissipation path for the array substrate 10 to improve the heat dissipation efficiency of the array substrate 10.

It should be noted that, in the above embodiment, the reflective unit 30 also extends to cover the second transparent portion 42 away from the surface of the array substrate 10, which may further reduce the signal transmission impedance in the second signal line 14, while extending the heat dissipation path of the array substrate 10, further improving the heat dissipation efficiency of the array substrate 10.

Optionally, in one embodiment, as shown in FIG. 31, the through hole 43 includes a first through hole area 431 and a second through hole area 432, where, in a direction X parallel to the plane where the display panel is located, the first through hole area 431 is located on the side of the light-emitting element 50 away from the second signal line 14, and the second through hole area 432 is located on the side of the light-emitting element 50 away from the first signal line 13. There is a first distance L1 between the first through hole area 431 and the light-emitting element 50, and there is a second distance L2 between the second through hole area 432 and the light-emitting element 50, and the first distance L1 is greater than the second distance L2, so that the first reflective portion 31 is closer to the light-emitting element 50. Therefore, the first reflective portion 31 may overlap with the second signal line 14, which is convenient for the electrical connection between the first reflective portion 31 and the second signal line 14. At the same time, the first reflective portion 31 does not overlap with the first electrode 11, thereby avoiding a short circuit between the first reflective portion 31 and the anode of the light-emitting unit 20.

On the basis of the above embodiments, in one embodiment, as shown in FIGS. 30 and 31, the first reflective portion 31 and the side surface of the light-emitting unit 20 are inclined in the same direction, for example, the first reflective portion 31 located on the side surface of the light-emitting unit 20 away from the first signal line 13 and the side surface of the light-emitting unit 20 away from the first signal line 13 are inclined to the lower left. The first reflective portion 31 located on the side of the light-emitting unit 20 away from the second signal line 14 and the side of the light-emitting unit 20 away from the second signal line 14 are inclined to the lower right. Optionally, in one embodiment, the angle between the first reflective portion 31 and the plane where the array substrate 10 is located is the first inclination angle α, and the angle between the side surface of the light-emitting unit 20 and the plane where the array substrate 10 is located is the second inclination angle θ. The first inclination angle α is less than the second inclination angle θ, so as to avoid the first reflective portion 31 being too steep, affecting the amount of light emitted from the light-emitting side of the light-emitting unit 20 within the light reflected by the first reflective portion 31. However, the present disclosure is not limited thereto, and it depends on the specific situation.

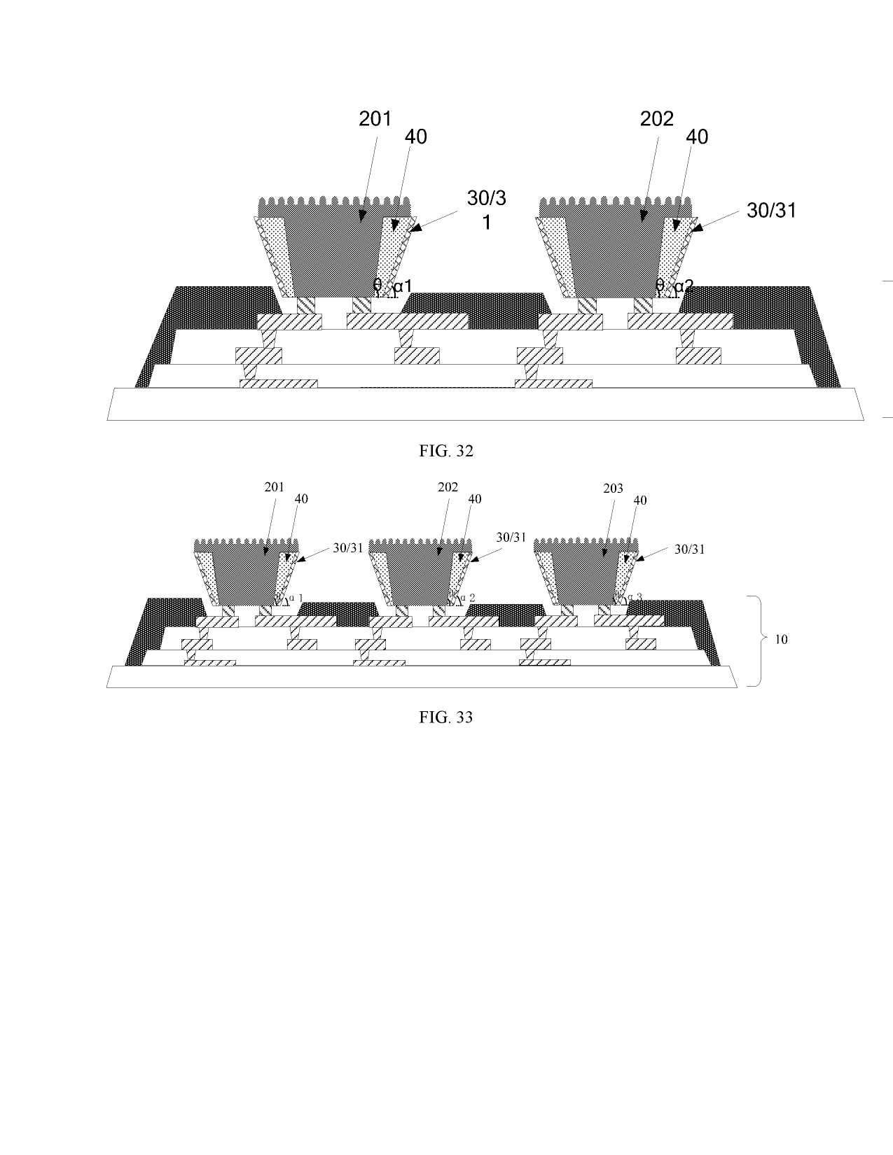

On the basis of the above embodiments, in one embodiment, as shown in FIG. 32, the display panel includes a first type of light-emitting unit 201 and a second type of light-emitting unit 202, and the first type of light-emitting unit 201 and the second type of light-emitting unit 202 are light-emitting units of different colors. It should be noted that under the same driving signal, the light-emitting brightness of light-emitting units of different colors is different. Therefore, in one embodiment of the present disclosure, a first angle α1 is formed between a first reflective portion 31 corresponding to the first type of light-emitting unit 201 and the plane where the array substrate 10 is located. A second angle α2 is formed between the first reflective portion 31 corresponding to the second type of light-emitting unit 202 and the plane where the array substrate 10 is located. The first angle α1 and the second angle α2 are different, so that by setting the first angle and the second angle to be different, the light extraction efficiency of the first type of light-emitting unit and the second type of light-emitting unit is different, thereby balancing the light-emitting brightness of the first type of light-emitting unit and the second type of light-emitting unit under the same driving signal.

On the basis of the above embodiments, in one embodiment, as shown in FIG. 33, the display panel further includes a third light-emitting unit 203, and the first type of light-emitting unit 201, the second type of light-emitting unit 202 and the third light-emitting unit are light-emitting units of different colors. It should be noted that, under the same driving signal, the light-emitting brightness of the light-emitting units of different colors is different. Therefore, in one embodiment of the present disclosure, a first angle α1 is formed between the first reflective portion 31 corresponding to the first type of light-emitting unit 201 and the plane where the array substrate 10 is located, a second angle α2 is formed between the first reflective portion 31 corresponding to the second type of light-emitting unit 202 and the plane where the array substrate 10 is located, and a third angle α3 is formed between the first reflective portion 31 corresponding to the third light-emitting unit 203 and the plane where the array substrate 10 is located. The first angle α1, the second angle α2 and the third angle α3 are different, so that by setting the first angle, the second angle and the third angle to be different, the light extraction efficiencies of the first type of light-emitting unit, the second type of light-emitting unit and the third light-emitting unit are different, thereby balancing the light-emitting brightness of the first type of light-emitting unit, the second type of light-emitting unit and the third light-emitting unit under the same driving signal.

Specifically, in one embodiment, the first type of light-emitting unit is a red light-emitting unit, the second type of light-emitting unit is a blue light-emitting unit, and the third light-emitting unit is a green light-emitting unit. The luminous efficiency of the green light-emitting unit is greater than the luminous efficiency of the red light-emitting unit, which is greater than the luminous efficiency of the blue light-emitting unit. Therefore, in one embodiment of the present disclosure, the second angle is greater than the first angle, which is greater than the third angle, so that the light reflectivity of the first reflective portion corresponding to the blue light-emitting unit is greater than the light reflectivity of the first reflective portion corresponding to the red light-emitting unit, which is greater than the light reflectivity of the first reflective portion corresponding to the green light-emitting unit, so as to balance the luminous brightness of the first type of light-emitting unit, the second type of light-emitting unit and the third light-emitting unit under the same driving signal.

Since the luminous brightness of light-emitting units of different colors is different, on the basis of the above embodiments, in one embodiment, the display panel includes a first type of light-emitting unit and a second type of light-emitting unit, and the first type of light-emitting unit and the second type of light-emitting unit are light-emitting units of different colors. The first reflective portion corresponding to the first type of light-emitting unit has a first reflectivity, and the first reflective portion corresponding to the second type of light-emitting unit has a second reflectivity. The first reflectivity and the second reflectivity are different, so that the light extraction efficiencies of the first type of light-emitting unit and the second type of light-emitting unit are different by setting the first reflectivity and the second reflectivity to be different, thereby balancing the luminous brightness of the first type of light-emitting unit and the second type of light-emitting unit under the same driving signal.

Optionally, on the basis of the above embodiments, in one embodiment, the display panel also includes a third light-emitting unit, and the first type of light-emitting unit, the second type of light-emitting unit and the third light-emitting unit are light-emitting units of different colors. The first reflective portion corresponding to the first type of light-emitting unit has a first reflectivity, the first reflective portion corresponding to the second type of light-emitting unit has a second reflectivity, and the first reflective portion corresponding to the third light-emitting unit has a third reflectivity. The first reflectivity, the second reflectivity and the third reflectivity are different, so that the light extraction efficiencies of the first type of light-emitting unit, the second type of light-emitting unit and the third light-emitting unit are different by setting the first reflectivity, the second reflectivity and the third reflectivity to be different, thereby balancing the luminous brightness of the first type of light-emitting unit, the second type of light-emitting unit and the third type of light-emitting unit under the same driving signal.

Specifically, in one embodiment, the first type of light-emitting unit is a red light-emitting unit, the second type of light-emitting unit is a blue light-emitting unit, and the third light-emitting unit is a green light-emitting unit. The luminous efficiency of the green light-emitting unit is greater than the luminous efficiency of the red light-emitting unit, which is greater than the luminous efficiency of the blue light-emitting unit. Therefore, in one embodiment of the present disclosure, the second reflectivity is greater than the first reflectivity and greater than the third reflectivity, so that the light reflectivity of the first reflective portion corresponding to the blue light-emitting unit is greater than the light reflectivity of the first reflective portion corresponding to the red light-emitting unit, which is greater than the light reflectivity of the first reflective portion corresponding to the green light-emitting unit. This then balances the luminous brightness of the first type of light-emitting unit, the second type of light-emitting unit and the third light-emitting unit under the same driving signal.

In addition, the present disclosure also provides a display device, which may include the display panel provided in the above embodiments. Since the relevant contents of the display panel have been described in the above embodiments, they will not be repeated here. Optionally, in the embodiments of the present disclosure, the display device may be a mobile phone, a tablet computer, a wearable device, a vehicle-mounted device, an augmented reality (AR)/virtual reality (VR) device, a laptop computer, an ultra-mobile personal computer (UMPC), a netbook, a personal digital assistant (PDA), etc., which is not limited in the present disclosure.

Overall, the display panel and the display device including the display panel provided in the embodiments of the present disclosure, in addition to the light-emitting units, also include reflective units, and a reflective unit includes a first reflective portion. The first reflective portion is located on at least one side surface of the corresponding light-emitting unit, and reflects the light emitted from at least one side surface of the corresponding light-emitting unit to the display side of the display panel, so that the light emitted from at least one side surface of the light-emitting unit is emitted from above the area where the light-emitting unit is located. This thus improves the light extraction efficiency of the light-emitting unit, thereby improving the light-emitting efficiency of the light-emitting unit under the premise that the size of the light-emitting unit is fixed, so as to improve the display brightness of the display panel under the same driving signal when applied to a high-resolution display panel, and alleviate the problem of difficulty in balancing high resolution and high-brightness display of display products.

Moreover, the display panel and the display device including the display panel provided in the embodiments of the present disclosure further include a transparent portion, which is located on the first side of the array substrate. At least part of the transparent portion is located between the first reflective portion and the light-emitting unit, so that there is a certain distance between the light-emitting unit and the first reflective portion, so that the light emitted from at least one side surface of the light-emitting unit may pass through the transparent portion, hit the first reflective portion, be reflected by the first reflective portion, and then pass through the transparent portion to be emitted from the light-emitting side of the light-emitting unit. In this process, part of the light will also be emitted from the side of the transparent portion away from the array substrate, thereby increasing the light emission area of the light-emitting area corresponding to each light-emitting unit.

In addition, the light-emitting area corresponding to each light-emitting unit will inevitably have edge effects when emitting light. That is, when the light-emitting area corresponding to each light-emitting unit emits light, it is difficult to make the amount of light emitted from the edge areas and the amount of light emitted from the central area completely consistent. In the disclosed embodiment, a transparent portion is also provided between the light-emitting unit and the first reflective portion, so that an edge effect area of each light-emitting area may be located in the area where the transparent portion is located, thereby improving the light uniformity of the light-emitting area directly above each light-emitting unit, thereby improving the display brightness uniformity of the display panel.

In addition, a transparent portion is arranged between the light-emitting unit and the first reflective portion. By setting the angle between the transparent portion and the plane where the array substrate is located and the refractive index of the transparent portion, the emission angle of the light formed after the light reflected by the first reflective portion is refracted on the side of the light-emitting unit may be reduced. That is, the angle between the emission direction of the light formed after the light reflected by the first reflective portion is refracted on the side of the light-emitting unit and the light emission direction of the light-emitting unit is reduced, so that the light reflected by the first reflective portion 31 is emitted from directly above the light-emitting unit as much as possible, thereby improving the light extraction efficiency of the light-emitting unit. When applied to a high-resolution display panel, under the same driving signal, the display brightness of the display panel is further improved, alleviating the problem of the difficulty in balancing the display products between high resolution and high brightness display.

The various embodiments in this specification are described in a progressive, parallel, or progressive and parallel manner. Each embodiment focuses on the differences from other embodiments, and the same or similar parts between the various embodiments may refer to each other.

It should be noted that in the description of the present disclosure, the description of the drawings and embodiments is illustrative rather than restrictive. The same figure labels throughout the embodiments of the specification identify the same structure. It should also be noted that, in this disclosure, relational terms such as first and second, etc., are merely used to distinguish one entity or operation from another entity or operation, and do not necessarily require or imply that there is any such actual relationship or order between these entities or operations. Moreover, the term “include”, “comprise” or any other variant thereof is intended to cover non-exclusive inclusion, so that an article or equipment including a series of elements includes not only those elements, but also other elements that are not clearly listed, or also includes elements inherent to such articles or equipment. In the absence of more restrictions, the elements limited by the sentence “including one...” do not exclude the existence of other identical elements in the article or equipment including the above elements.

The above description of the disclosed embodiments enables those skilled in the art to implement or use the present disclosure. Various modifications to these embodiments will be apparent to those skilled in the art, and the general principles defined herein may be implemented in other embodiments without departing from the spirit or scope of the present disclosure. Therefore, the present disclosure will not be limited to the embodiments shown herein, but will conform to the widest scope consistent with the principles and novel features disclosed herein.

What is claimed is:

1. A display panel, comprising:
an array substrate;
a plurality of light-emitting units and a plurality of reflective units located on a first side of the array substrate, wherein a reflective unit includes a first reflective portion, and the first reflective portion is located on at least one side surface of a corresponding light-emitting unit; and
a transparent portion located on the first side of the array substrate, wherein at least a part of the transparent portion is located between the first reflective portion and the corresponding light-emitting unit.

2. The display panel according to claim 1, wherein the transparent portion is in direct contact with the side surface of the light-emitting unit, and/or the transparent portion is in direct contact with the reflective unit.

3. The display panel according to claim 1, wherein the display panel includes a plurality of light-emitting areas, a light-emitting area is provided with a light-emitting element, and the light-emitting element includes the light-emitting unit and the first reflective portion.

4. The display panel according to claim 3, wherein the light-emitting unit includes a buffer layer and a light-emitting portion located on one side of the buffer layer, wherein the buffer layer includes a first region and a second region at least partially surrounding the first region, the light-emitting portion is located in the first region, and the first reflective portion is located in the second region.

5. The display panel according to claim 4, wherein:
in a direction parallel to a plane where the display panel is located, a distance from the first reflective portion to a side of the second region of the buffer layer away from the first region is greater than zero; or
the display panel includes a first type of light-emitting unit and a second type of light-emitting unit, and the first type of light-emitting unit and the second type of light-emitting unit are light-emitting units of different colors; and
in a plane parallel to the array substrate, a second region of the first type of light-emitting unit has a first width, a second region of the second type of light-emitting unit has a second width, and the first width is different from the second width.

6. The display panel according to claim 3, wherein the light-emitting unit includes a buffer layer and a light-emitting portion located on a surface of the buffer layer, and an area of a surface of the light-emitting portion facing the buffer layer is identical to an area of a surface of the buffer layer facing the light-emitting portion.

7. The display panel according to claim 1, wherein the first reflective portion is a Bragg reflective layer, and the first reflective portion also covers an area between adjacent light-emitting units.

8. The display panel according to claim 1, wherein the display panel includes a plurality of light-emitting areas, a light-emitting area is provided with a light-emitting element, the light-emitting element includes the light-emitting unit, there is a gap between the first reflective portion and the light-emitting element, and the transparent portion is at least partially located between the first reflective portion and the light-emitting element.

9. The display panel according to claim 8, wherein:
the transparent portion at least covers an area between adjacent light-emitting elements and exposes the light-emitting area of the light-emitting element away from the array substrate; and
the transparent portion includes a first transparent portion and a second transparent portion, wherein the first transparent portion is located at a side of the light-emitting element, a through hole is provided between the second transparent portion and the first transparent portion, and the first reflective portion is located in the through hole.

10. The display panel according to claim 8, wherein the transparent portion also covers a surface of the light-emitting unit away from the array substrate.

11. The display panel according to claim 9, wherein an area of the through hole away from the array substrate is larger than an area of the through hole close to the array substrate, and the first reflective portion is located on a side of the through hole away from the light-emitting element.

12. The display panel according to claim 9, wherein an area of the through hole away from the array substrate is smaller than an area of the through hole close to the array substrate, and the first reflective portion is located on a side of the through hole close to the light-emitting element.

13. The display panel according to claim 12, wherein the reflective unit further includes a second reflective portion, and the second reflective portion is located at a side of the through hole away from the light-emitting element and a bottom of the through hole.

14. The display panel according to claim 11, wherein:
the reflective unit also covers a surface of the second transparent portion away from the array substrate; and
the display panel further includes a shielding unit, and the shielding unit covers a portion of the reflective unit located on the surface of the second transparent portion.

15. The display panel according to claim 9, wherein:
the array substrate includes a first electrode and a second electrode located on a surface of the array substrate and a first signal line and a second signal line located inside the array substrate, the first signal line is electrically connected to a positive electrode of the light-emitting unit through the first electrode, and the second signal line is electrically connected to a negative electrode of the light-emitting unit through the second electrode; and
the first reflective portion is electrically connected to the second signal line.

16. The display panel according to claim 15, wherein the through hole includes a first through hole area and a second through hole area, wherein, in a direction parallel to a plane where the display panel is located, the first through hole area is located on a side of the light-emitting element away from the second signal line, the second through hole area is located on a side of the light-emitting element away from the first signal line, a first distance exists between the first through hole area and the light-emitting element, a second distance exists between the second through hole area and the light-emitting element, and the first distance is greater than the second distance.

17. The display panel according to claim 1, wherein inclination directions of the first reflective portion and the side surface of the light-emitting unit are consistent, and an angle between the first reflective portion and a plane where the array substrate is located is a first inclination angle, an angle between the side surface of the light-emitting unit and the plane where the array substrate is located is a second inclination angle, and the first inclination angle is smaller than the second inclination angle.

18. The display panel according to claim 1, wherein:
the display panel includes a first type of light-emitting unit and a second type of light-emitting unit, and the first type of light-emitting unit and the second type of light-emitting unit are light-emitting units of different colors;
a first angle is formed between a first reflective portion corresponding to the first type of light-emitting unit and a plane where the array substrate is located;
a second angle is formed between a first reflective portion corresponding to the second type of light-emitting unit and the plane where the array substrate is located; and
the first angle and the second angle are different.

19. The display panel according to claim 1, wherein:
the display panel includes a first type of light-emitting unit and a second type of light-emitting unit, and the first type of light-emitting unit and the second type of light-emitting unit are light-emitting units of different colors;
a first reflective portion corresponding to the first type of light-emitting unit has a first reflectivity;
a first reflective portion corresponding to the second type of light-emitting unit has a second reflectivity; and
the first reflectivity and the second reflectivity are different.

20. A display device, including a display panel, and the display panel comprising:
an array substrate;
a plurality of light-emitting units and a plurality of reflective units located on a first side of the array substrate, wherein a reflective unit includes a first reflective portion, and the first reflective portion is located on at least one side surface of a corresponding light-emitting unit; and
a transparent portion located on the first side of the array substrate, wherein at least a part of the transparent portion is located between the first reflective portion and the corresponding light-emitting unit.
